(19) United States
(12) Patent Application Publication
(10) Pub. No.: US 2025/0202445 A1
(43) Pub. Date: Jun. 19, 2025

(54) FEEDFORWARD OFFSET CANCELLATION OF ANALOG AMPLIFIER USING OUTPUT AUTO-ZEROED GAIN STAGES

(71) Applicant: Cirrus Logic International Semiconductor Ltd., Edinburgh (GB)

(72) Inventors: Arashk NOROUZPOURSHIRAZI, Austin, TX (US); Axel THOMSEN, Austin, TX (US)

(73) Assignee: Cirrus Logic International Semiconductor Ltd., Edinburgh (GB)

(21) Appl. No.: 18/543,896

(22) Filed: Dec. 18, 2023

(51) Int. Cl. H03F 3/45

(52) U.S. Cl. CPC H03F 3/45475; H03F 2200/375

(57) ABSTRACT

A system may include an analog amplifier configured to receive an input signal and generate an output signal based on the input signal and a sidecar amplifier coupled to the analog amplifier and configured to generate a compensation signal applied to the analog amplifier in order to correct a signal offset associated with the analog amplifier, the sidecar amplifier comprising a plurality of amplifier stages, each amplifier stage having a respective gain at least 10 decibels smaller than an overall gain of the sidecar amplifier.

### FIELD OF DISCLOSURE

The present disclosure relates in general to systems and method for cancelling offset in an analog amplifier using an auxiliary sidecar amplifier having one or more output auto-zeroed gain stages.

### BACKGROUND

Analog amplifiers have many uses in electronics, including being used to implement an analog front end for analog-to-digital converters, and numerous other issues. One problem that often exists in analog amplifiers is the presence of an offset, whereby a non-zero output is generated at an output of the analog amplifier even when the input voltage or other input signal to the analog amplifier is zero.

A number of approaches have been used to provide cancellation or compensation for such offset, but many of these approaches have disadvantages. For example, main signal path chopping has been used to compensate for offset, but chopping may lead to undesirable ripple at the chopping frequency and internal node settling may negatively impact loop gain and accuracy. Another example approach is chopper stabilization, which may require high levels of power consumption to maintain settling behavior. A further approach is the use of a sidecar amplifier that measures the offset and modifies the voltage bias of the analog amplifier to compensate for the offset. However, existing approaches using sidecar amplifiers require a sampling process that increases overall amplifier noise and requires large storing capacitances for storing offset values. Such existing approaches for sidecar amplifiers also require switching at the input nodes of the sidecar amplifier, requiring higher input capacitance, and the charge injection of input switches may lead to additional error. Further, in such existing approaches, low-frequency noise reduction is dependent on switching speed of auto-zeroing of the sidecar amplifier, and higher switching speeds require larger amounts of power consumption.

### SUMMARY

In accordance with the teachings of the present disclosure, the disadvantages and problems associated with correcting for offset in an analog amplifier may be reduced or eliminated.

In accordance with embodiments of the present disclosure, a system may include an analog amplifier configured to receive an input signal and generate an output signal based on the input signal and a sidecar amplifier coupled to the analog amplifier and configured to generate a compensation signal applied to the analog amplifier in order to correct a signal offset associated with the analog amplifier, the sidecar amplifier comprising a plurality of amplifier stages, each amplifier stage having a respective gain at least 10 decibels smaller than an overall gain of the sidecar amplifier.

In accordance with these and other embodiments of the present disclosure, a method may include generating, by an analog amplifier, an output signal based on an input signal to the analog amplifier and generating, with a sidecar amplifier coupled to the analog amplifier, a compensation signal applied to the analog amplifier in order to correct a signal offset associated with the analog amplifier, the sidecar amplifier comprising a plurality of amplifier stages, each amplifier stage having a respective gain at least 10 decibels smaller than an overall gain of the sidecar amplifier.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an example circuit diagram of an analog amplifier electrically coupled to a sidecar amplifier configured to provide for feedforward cancellation of offset of the analog amplifier, in accordance with embodiments of the present disclosure;

FIG. 2 illustrates a circuit diagram of an example sidecar amplifier, in accordance with embodiments of the present disclosure;

FIG. 3 illustrates a circuit diagram of another example sidecar amplifier, in accordance with embodiments of the present disclosure;

FIG. 4 illustrates a circuit diagram of an additional example sidecar amplifier, in accordance with embodiments of the present disclosure; and

FIGS. 5A-5C (which may be referred to collectively herein as “FIG. 5”) illustrate a circuit diagram of yet another example sidecar amplifier, in accordance with embodiments of the present disclosure.

### DETAILED DESCRIPTION

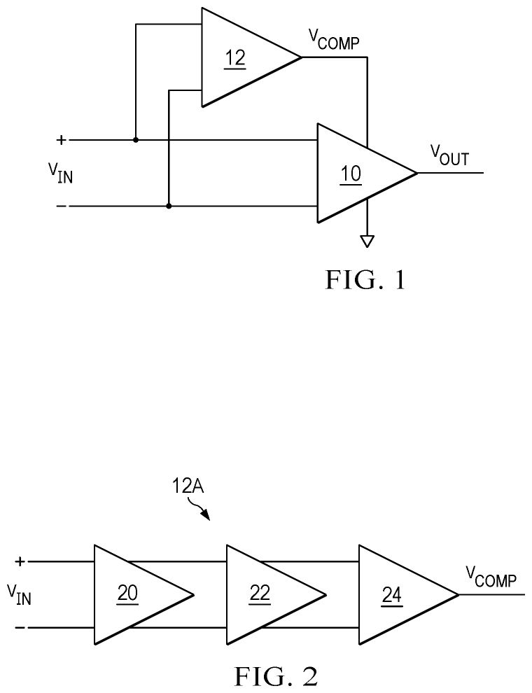

FIG. 1 illustrates an example circuit diagram of an analog amplifier 10 electrically coupled to a sidecar amplifier 12 configured to provide for feedforward cancellation of offset of analog amplifier 10, in accordance with embodiments of the present disclosure. As shown in FIG. 1, analog amplifier 10 may receive and amplify an input voltage V_{IN} to generate an output voltage V_{OUT}. For purposes of clarity and exposition, analog amplifier 10 is shown as having a single-ended output for generating output voltage V_{OUT}. However, in some embodiments, analog amplifier 10 may have a differential output.

Sidecar amplifier 12 may receive and amplify input voltage V_{IN} to generate a compensation voltage V_{COMP} in order to control biasing of analog amplifier 10 in a manner to compensate (e.g., cancel, correct, etc.) for the offset of analog amplifier 10. In operation, sidecar amplifier 12 may perform auto-zeroing by sensing the input-referred offset of analog amplifier 10 while in a closed-loop configuration and countering an offset current of analog amplifier 10 by controlling biasing of analog amplifier 10. In particular, auto-zeroing may comprise shorting together the differential inputs of sidecar amplifier 12, sensing the output-referred offset within sidecar amplifier 12, and storing such sensed output-referred offset to be applied to generate compensation voltage V_{COMP}.

In general, the concept of controlling biasing of an amplifier to compensate for offset is well-known and is beyond the scope of this disclosure, and a focus of the present disclosure is sidecar amplifiers 12 improved over traditional sidecar amplifiers 12. The present disclosure describes example embodiments of sidecar amplifier 12 in greater detail below.

FIG. 2 illustrates a circuit diagram of an example sidecar amplifier 12A, in accordance with embodiments of the present disclosure. In some embodiments, sidecar amplifier 12A shown in FIG. 2 may be used to implement sidecar amplifier 12 shown in FIG. 1. As shown in FIG. 2, sidecar amplifier 12A may comprise a plurality of cascaded amplifier stages 20, 22, and 24. Each amplifier stage 20, 22, and 24 may comprise a low-gain amplifier stage having a gain that is at least 10 decibels lower than the overall path gain of sidecar amplifier 12A, and that consumes significantly lower power than if a single stage were used to implement a sidecar amplifier having the same overall path gain of sidecar amplifier 12A. The plurality of amplifier stages 20, 22, and 24 may enable sidecar amplifier 12A to have a high gain and high bandwidth.

Although FIG. 2 depicts sidecar amplifier 12A having three amplifier stages 20, 22, and 24, it is understood that sidecar amplifier 12A may include any suitable number of two or more amplifier stages.

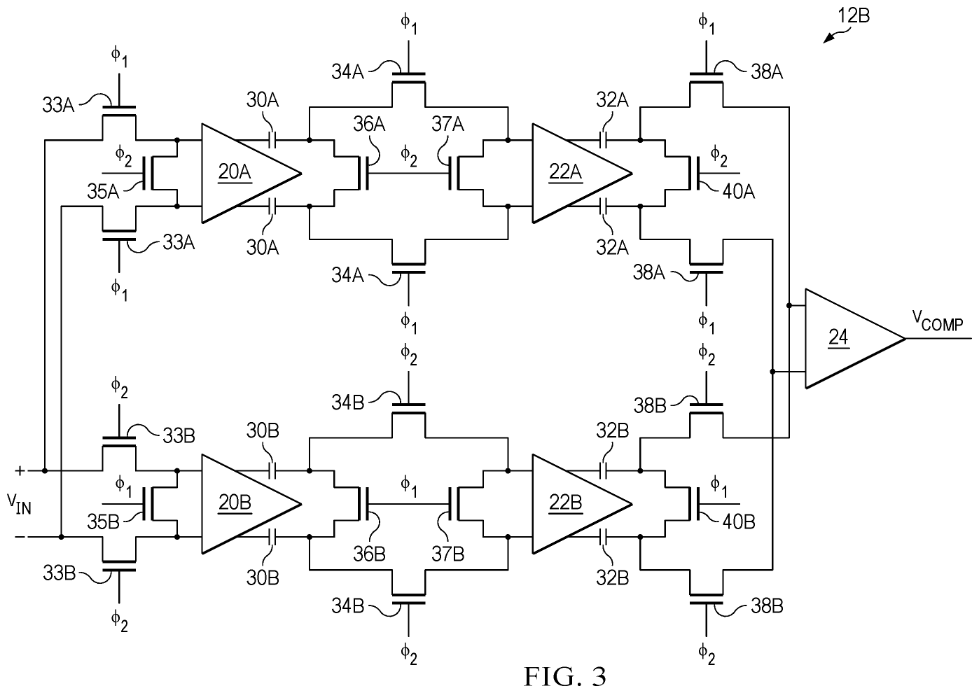

Those of skill in the art may recognize that each amplifier stage of sidecar amplifier 20, 22, and 24 may have its own offset, which may benefit from offset compensation. Accordingly, amplifier stages 20 and 22 (i.e., all amplifier stages other than final amplifier stage 24) may themselves be auto-zeroed, as described in greater detail below with respect to FIG. 3.

FIG. 3 illustrates a circuit diagram of an example sidecar amplifier 12B, in accordance with embodiments of the present disclosure. In some embodiments, sidecar amplifier 12B shown in FIG. 3 may be used to implement sidecar amplifier 12 shown in FIG. 1. Sidecar amplifier 12B may be similar in many respects to sidecar amplifier 12A depicted in FIG. 2, and thus, only certain differences between sidecar amplifier 12A and sidecar amplifier 12B may be described below.

As shown in FIG. 3, amplifier stage 20 may be split into two amplifier stages 20A and 20B, and amplifier stage 22 may be split into two amplifier stages 22A and 22B, such that amplifier stage 20A and amplifier stage 22A are in a first signal path parallel to a second signal path comprising amplifier stage 20B and amplifier stage 22B.

Amplifier stage 20A may have input switches 33A coupled to its respective input terminals and an input zeroing switch 35A coupled across its terminals. Similarly, amplifier stage 20B may have input switches 33B coupled to its respective input terminals and an input zeroing switch 35B coupled across its terminals. Amplifier stage 20A may have storage capacitors 30A coupled at each of its differential outputs for storing an offset associated with amplifier stage 20A. Likewise, amplifier stage 20B may have storage capacitors 30B coupled at each of its differential outputs for storing an offset associated with amplifier stage 20B. Interstage switches 34A may be coupled between each capacitor 30A and an input terminal of amplifier stage 22A. Similarly, interstage switches 34B may be coupled between each capacitor 30B and an input terminal of amplifier stage 22B. In addition, zeroing switch 36A may be coupled between capacitors 30A at the output of amplifier stage 20A and zeroing switch 36B may be coupled between capacitors 30B at the output of amplifier stage 20B.

In some embodiments, amplifier stages 20A and 20B may be designed with input devices having a small device size (e.g., significantly smaller than input device sizes of analog amplifier 10) in order to minimize input capacitance of sidecar amplifier 12B.

Amplifier stage 22A may have an input zeroing switch 37A coupled across its terminals. Similarly, amplifier stage 22B may have an input zeroing switch 37B coupled across its terminals. Amplifier stage 22A may have storage capacitors 32A coupled at each of its differential outputs for storing an offset associated with amplifier stage 22A. Likewise, amplifier stage 22B may have storage capacitors 32B coupled at each of its differential outputs for storing an offset associated with amplifier stage 22B. Interstage switches 38A may be coupled between each capacitor 32A and an input terminal of amplifier stage 24. Similarly, interstage switches 38B may be coupled between each capacitor 32B and an input terminal of amplifier stage 24. In addition, zeroing switch 40A may be coupled between capacitors 32A at the output of amplifier stage 22A and zeroing switch 40B may be coupled between capacitors 32B at the output of amplifier stage 22B.

In operation, in a first phase ϕ₁ of sidecar amplifier 12B, input switches 33A, interstage switches 34A, interstage switches 38A, zeroing switch 35B, zeroing switch 36B, zeroing switch 37B and zeroing switch 40B may close and interstage switches 34B, interstage switches 38B, zeroing switch 35A, zeroing switch 36A, zeroing switch 37A and zeroing switch 40A may open. Accordingly, storage capacitors 30A and 32A may cancel the offsets of the amplifier stages 20A and 22A respectively, and storage capacitors 30B and 32B may store a voltage indicative of offsets of amplifier stages 20B and 22B.

Similarly, in a second phase ϕ₂ of sidecar amplifier 12B, input switches 33B, interstage switches 34B, interstage switches 38B, zeroing switch 35A, zeroing switch 36A, zeroing switch 37A and zeroing switch 40A may close and interstage switches 34A, interstage switches 38A, zeroing switch 35B, zeroing switch 36B, zeroing switch 37B and zeroing switch 40B may open. Accordingly, storage capacitors 30B and 32B may cancel the offsets of the amplifier stages 20B and 22B respectively, and storage capacitors 30A and 32A may store a voltage indicative of offsets of amplifier stages 20A and 22A.

Output amplifier stage 24 may not include auto zeroing, but instead may serve as a summing amplifier to generate compensation voltage V_{COMP} from the first path including amplifier stages 20A and 22A during first phase ϕ₁ and generate compensation voltage V_{COMP} from the second path including amplifier stages 20B and 22B during second phase ϕ₂. In some embodiments, output amplifier stage 24 may be designed to have a lower raw offset such that it may not require auto zeroing as in amplifier stages 20A, 20B, 22A, and 22B.

In some embodiments, output amplifier stage 24 may include an integrating or low-pass filter stage in order to isolate the frequency response of sidecar amplifier 12 from the frequency response of analog amplifier 10. In other embodiments, a low-pass filter (not explicitly shown) may be added within the signal path of sidecar amplifier 12 in order to provide desired filtering and isolation of frequency responses.

Sidecar amplifier 12B may perform auto-zeroing in an alternating “ping-pong” fashion, wherein one path of sidecar amplifier 12B is in amplification and participating in generation of compensation voltage V_{COMP} while the second path is auto-zeroing and vice versa. As a result, higher-frequency switching may be performed at an overall high feedforward gain to minimize output offset. Sidecar amplifier 12B may also use a near-zero input current dominated only by switch charge injection.

Although FIG. 3 depicts sidecar amplifier 12B having two auto-zeroing amplifier stages (e.g., amplifier stage 20A/20B and amplifier stage 22A/22B) and one output amplifier stage 24, it is understood that sidecar amplifier 12B may include any suitable number of one or more auto-zeroing amplifier stages.

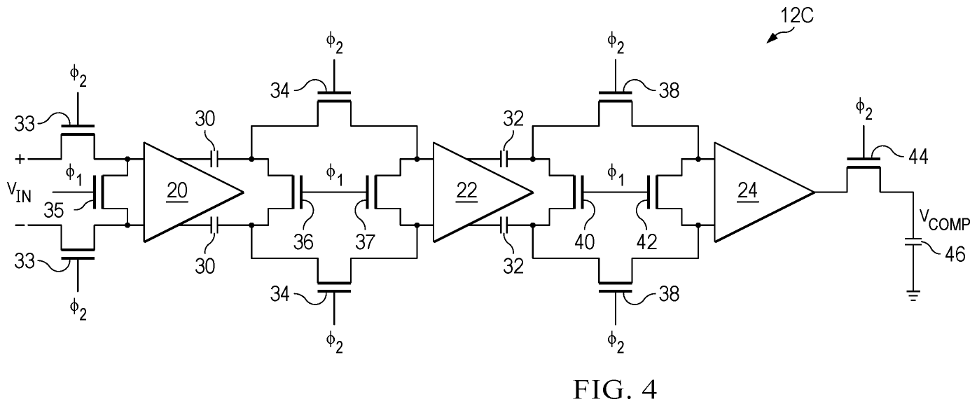

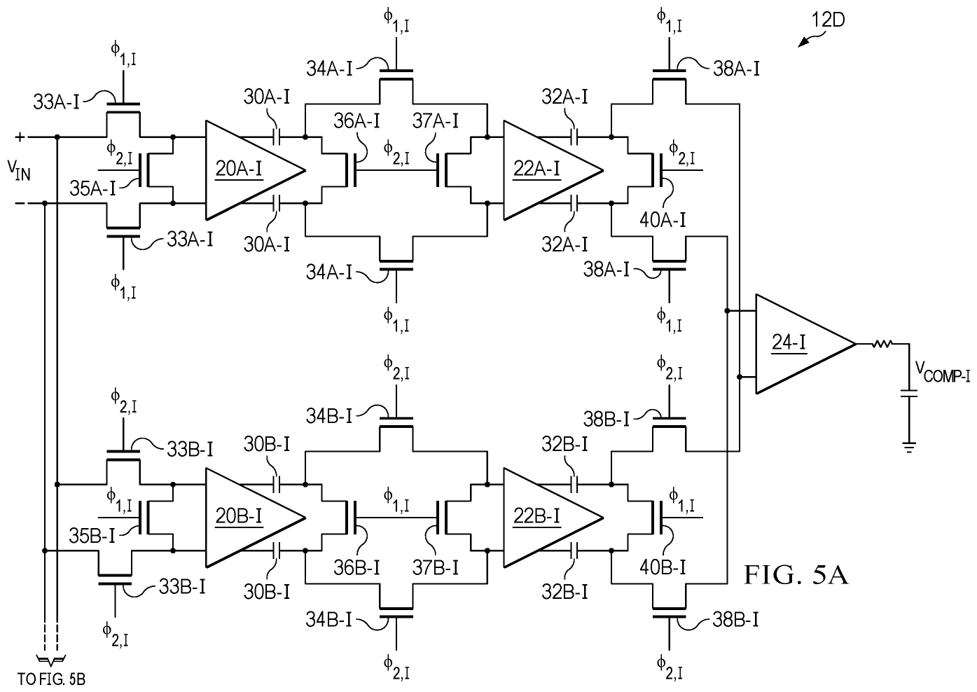

FIG. 4 illustrates a circuit diagram of an example sidecar amplifier 12C, in accordance with embodiments of the present disclosure. In some embodiments, sidecar amplifier 12C shown in FIG. 4 may be used to implement sidecar amplifier 12 shown in FIG. 1. Sidecar amplifier 12C may be similar in many respects to sidecar amplifier 12B depicted in FIG. 3, and thus, only certain differences between sidecar amplifier 12B and sidecar amplifier 12C may be described below.

Amplifier stage 20 may have input switches 33 coupled to its respective input terminals and an input zeroing switch 35 coupled across its terminals. Amplifier stage 20 may have storage capacitors 30 coupled at each of its differential outputs for storing an offset associated with amplifier stage 20. Interstage switches 34 may be coupled between each capacitor 30 and an input terminal of amplifier stage 22. In addition, zeroing switch 36 may be coupled between capacitors 30 at the output of amplifier stage 20. In some embodiments, amplifier stage 20 may be designed with input devices having a small device size (e.g., significantly smaller than input device sizes of analog amplifier 10) in order to minimize input capacitance of sidecar amplifier 12C.

Amplifier stage 22 may have an input zeroing switch 37 coupled across its terminals. Amplifier stage 22 may have storage capacitors 32 coupled at each of its differential outputs for storing an offset associated with amplifier stage 22. Interstage switches 38 may be coupled between each capacitor 32 and an input terminal of amplifier stage 24. In addition, zeroing switch 40 may be coupled between capacitors 32 at the output of amplifier stage 22.

Output amplifier stage 24 may have an input zeroing switch 42 coupled across its terminals. Further, output amplifier stage 24 may have an output switch 44 coupled between the output terminal of output amplifier stage 24 and a hold capacitor 46.

In operation, in a first phase ϕ₁ of sidecar amplifier 12C, zeroing switch 35, zeroing switch 36, zeroing switch 37, zeroing switch 40, and zeroing switch 42 may close and interstage switches 34, interstage switches 38, and output switch 44 may open. Accordingly, hold capacitor 46 may hold a sampled compensation voltage V_{COMP} from the previous sampling cycle, while storage capacitors 30 and 32 may store voltages indicative of offsets of the amplifier stages 20 and 22 respectively. In a second phase ϕ₂ of sidecar amplifier 12C, input switches 33, interstage switches 34, interstage switches 38, and output switch 44 may close and zeroing switch 35, zeroing switch 36, zeroing switch 37, zeroing switch 40 and zeroing switch 42 may open. Accordingly, storage capacitors 30 and 32 may cancel the offsets of the amplifier stages 20 and 22 respectively, with the offset voltages that they sampled during ϕ₁, and hold capacitor 46 may sample a new compensation voltage V_{COMP}.

In some embodiments, output amplifier stage 24 may include an integrating or low-pass filter stage in order to isolate the frequency response of sidecar amplifier 12 from the frequency response of analog amplifier 10. In other embodiments, a low-pass filter (not explicitly shown) may be added within the signal path of sidecar amplifier 12 in order to provide desired filtering and isolation of frequency responses.

Although FIG. 4 depicts sidecar amplifier 12C having two auto-zeroing amplifier stages (e.g., amplifier stage 20 and amplifier stage 22) and one output amplifier stage 24, it is understood that sidecar amplifier 12C may include any suitable number of one or more auto-zeroing amplifier stages.

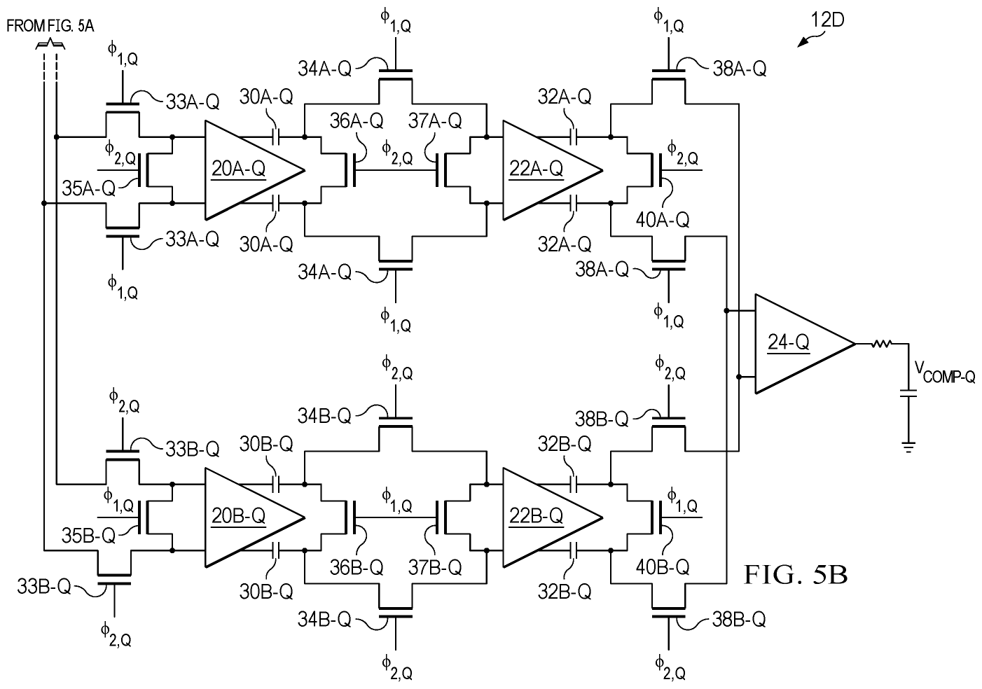

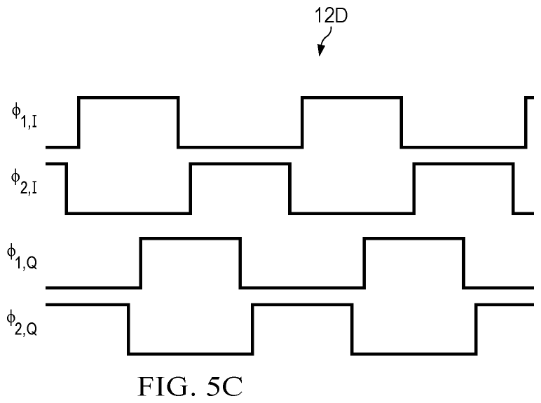

FIGS. 5A-5C illustrate a circuit diagram of an example sidecar amplifier 12D, in accordance with embodiments of the present disclosure. In some embodiments, sidecar amplifier 12D shown in FIG. 5 may be used to implement sidecar amplifier 12 shown in FIG. 1. Sidecar amplifier 12D may be similar in many respects to sidecar amplifier 12B depicted in FIG. 3, and thus, only certain differences between sidecar amplifier 12B and sidecar amplifier 12D may be described below.

In particular, example sidecar amplifier 12D is effectively two instances of sidecar amplifier 12B, with a first instance of sidecar amplifier 12B generating an in-phase channel (“-I”) compensation voltage V_{COMP-I}, as shown in FIG. 5A, and a second instance of sidecar amplifier 12B generating a quadrature-phase channel (“-Q”) compensation voltage V_{COMP-Q}, as shown in FIG. 5B Thus, to minimize potential signal aliasing, sidecar amplifier 12D may utilize four paths (e.g., two paths in in-phase channel and two paths in quadrature channel) with quadrature-phase clocking (as shown in FIG. 5C), each individual channel operating similar to that of sidecar amplifier 12B. Thus, in-phase channel compensation voltage V_{COMP-I} and quadrature channel compensation voltage V_{COMP-Q} may be applied to individual bias branches inside main amplifier 12.

Although FIG. 5 depicts sidecar amplifier 12D having two auto-zeroing amplifier stages (e.g., amplifier stages 20 and amplifier stages 22) and one output amplifier stage 24 in each channel, it is understood that sidecar amplifier 12C may include any suitable number of one or more auto-zeroing amplifier stages. Further, although FIG. 5 depicts sidecar amplifier 12D having four paths within two channels, in some embodiments sidecar amplifier 12D may have more than four paths within more than two channels by implementing more clock phases.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system comprising:
an analog amplifier configured to receive an input signal and generate an output signal based on the input signal; and
a sidecar amplifier coupled to the analog amplifier and configured to generate a compensation signal applied to the analog amplifier in order to correct a signal offset associated with the analog amplifier, the sidecar amplifier comprising a plurality of amplifier stages, each amplifier stage having a respective gain at least 10 decibels smaller than an overall gain of the sidecar amplifier.

2. The system of claim 1, wherein the sidecar amplifier comprises auto-zeroing circuitry configured to auto-zero an output of at least one amplifier stage of the plurality of amplifier stages.

3. The system of claim 2, wherein:
the at least one amplifier stage is split among a plurality of signal paths including at least a first signal path and a second signal path; and
the auto-zeroing circuitry is configured to alternatingly:
perform auto-zeroing on the first signal path of the at least one amplifier stage while enabling the second signal path of the at least one amplifier stage to perform amplification; and
perform auto-zeroing on the second signal path of the at least one amplifier stage while enabling the first signal path of the at least one amplifier stage to perform amplification.

4. The system of claim 3, wherein the plurality of amplifier stages includes an output amplifier stage configured to generate the compensation signal by amplifying an output stage input signal comprising:
the output of the first signal path when the first signal path is enabled to perform amplification; and
the output of the second signal path when the second signal path is enabled to perform amplification.

5. The system of claim 4, wherein the output amplifier stage is further configured to low-pass filter the output stage input signal to generate the compensation signal.

6. The system of claim 2, wherein the sidecar amplifier comprises a single path, wherein the compensation signal is stored on an output capacitor of the sidecar amplifier during an auto-zeroing phase of the sidecar amplifier.

7. The system of claim 2, wherein:
the sidecar amplifier includes at least two channels comprising an in-phase channel and a quadrature phase channel;
the at least one amplifier stage is split among a plurality of signal paths within each of the at least two channels, including at least a first signal path and a second signal path within each of the at least two channels;
the sidecar amplifier comprises auto-zeroing circuitry configured to the auto-zeroing circuitry configured to alternatingly, within each of the at least two channels:
perform auto-zeroing on the first signal path of the at least one amplifier stage while enabling the second signal path of the at least one amplifier stage to perform amplification; and
perform auto-zeroing on the second signal path of the at least one amplifier stage while enabling the first signal path of the at least one amplifier stage to perform amplification; and
the in-phase channel and the quadrature phase channel are clocked in quadrature phase relative to one another.

8. The system of claim 1, wherein the compensation signal controls electrical biasing of the analog amplifier.

9. A method comprising:
generating, by an analog amplifier, an output signal based on an input signal to the analog amplifier; and
generating, with a sidecar amplifier coupled to the analog amplifier, a compensation signal applied to the analog amplifier in order to correct a signal offset associated with the analog amplifier, the sidecar amplifier comprising a plurality of amplifier stages, each amplifier stage having a respective gain at least 10 decibels smaller than an overall gain of the sidecar amplifier.

10. The method of claim 9, further comprising auto-zeroing an output of at least one amplifier stage of the plurality of amplifier stages.

11. The method of claim 10, wherein:
the at least one amplifier stage is split among a plurality of signal paths including at least a first signal path and a second signal path; and
the method further comprises:
performing auto-zeroing on the first signal path of the at least one amplifier stage while enabling the second signal path of the at least one amplifier stage to perform amplification; and
performing auto-zeroing on the second signal path of the at least one amplifier stage while enabling the first signal path of the at least one amplifier stage to perform amplification.

12. The method of claim 11, wherein the plurality of amplifier stages includes an output amplifier stage configured to generate the compensation signal by amplifying an output stage input signal comprising:
the output of the first signal path when the first signal path is enabled to perform amplification; and
the output of the second signal path when the second signal path is enabled to perform amplification.

13. The method of claim 12, further comprising low-pass filtering the output stage input signal to generate the compensation signal.

14. The method of claim 10, wherein the sidecar amplifier comprises a single path, and the method further comprises storing the compensation signal on an output capacitor of the sidecar amplifier during an auto-zeroing phase of the sidecar amplifier.

15. The method of claim 10, wherein:
the sidecar amplifier includes at least two channels comprising an in-phase channel and a quadrature phase channel;
the at least one amplifier stage is split among a plurality of signal paths within each of the at least two channels, including at least a first signal path and a second signal path within each of the at least two channels;
the method further comprises alternatingly, within each of the at least two channels:
performing auto-zeroing on the first signal path of the at least one amplifier stage while enabling the second signal path of the at least one amplifier stage to perform amplification; and
performing auto-zeroing on the second signal path of the at least one amplifier stage while enabling the first signal path of the at least one amplifier stage to perform amplification; and
clocking the in-phase channel and the quadrature phase channel in quadrature phase relative to one another.

16. The method of claim 9, wherein the compensation signal controls electrical biasing of the analog amplifier.
